(19) United States
(12) Patent Application Publication
(10) Pub. No.: US 2026/0366162 A1
(43) Pub. Date: Nov. 19, 2026

(54) SUBSTRATE PROCESSING APPARATUS AND OPERATING METHOD THEREFOR

(71) Applicant: EUGENE TECHNOLOGY CO., LTD., Yongin-si, Gyeonggi-do (KR)

(72) Inventors: Jun Jin HYON, Yongin-si, Gyeonggi-do (KR); Jin Wook BAEK, Yongin-si, Gyeonggi-do (KR); Hyeong Sik KO, Yongin-si, Gyeonggi-do (KR); Hyun No LEE, Yongin-si, Gyeonggi-do (KR); Hyung Mo YANG, Yongin-si, Gyeonggi-do (KR)

(21) Appl. No.: 19/126,617

(22) PCT Filed: Nov. 23, 2023
(86) PCT No.: PCT/KR2023/019044

§ 371 Date: May 1, 2025

(30) Foreign Application Priority Data
Nov. 23, 2022 (KR) 10-2022-0158628

(51) Int. Cl. C23C 16/52; C23C 16/44; C23C 16/458; H10P 72/00

(52) U.S. Cl. CPC C23C 16/52; C23C 16/4408; C23C 16/4412; C23C 16/4583; H10P 72/0402

(57) ABSTRACT

The present inventive concept relates to a substrate processing apparatus which can secure safety while carrying out processes by supplying a toxic gas into a process chamber and an operating method therefor, and the substrate processing apparatus may comprise: a process chamber having an opening in one side thereof; a processing gas supply unit which supplies a processing gas including the toxic gas into the process chamber; an exhaust portion which exhausts the process chamber; an opening/closing means which opens/closes the opening of the process chamber; and a controller which interlocks the opening/closing means by sensing the supply of the toxic gas and releases the interlocking of the opening/closing means according to the internal pressure of the process chamber.

### TECHNICAL FIELD

The present inventive concept relates to a substrate processing apparatus and an operating method therefor, and more particularly, to a substrate processing apparatus and an operating method thereof, which are capable of securing safety while performing processes by supplying a toxic gas into a process chamber.

### BACKGROUND ART

In general, in a substrate processing apparatus, a toxic gas is supplied into a process chamber to perform processes. Since the toxic gas is harmful to the human body, it is important to prevent the toxic gas from leaking, and even when an opening of the process chamber is opened or closed to transfer a substrate such as a wafer, it is necessary to manage the toxic gas remaining in the process chamber from being escaped to the outside.

In particular, in a batch type substrate processing apparatus, since a person enters a loading chamber, which communicates with a process chamber to load a substrate on a substrate boat, it is necessary to thoroughly block an introduction of a toxic gas remaining in the process chamber into the loading chamber.

Thus, a technology for preventing an accident, which the residual toxic gas remaining in the process chamber leaks to the outside while opening and closing the opening of the process chamber, from occurring is required.
(Patent Document 1) Korean Patent Publication No. 10-2007-0045792

### DISCLOSURE OF THE INVENTIVE CONCEPT

### Technical Problem

The present inventive concept provides a substrate processing apparatus and an operating method therefor, in which an opening/closing means for opening and closing an opening of a process chamber is interlocked until a toxic gas is exhausted from the process chamber to prevent the toxic gas remaining in the process chamber from leaking to the outside, while performing a process by supplying the toxic gas into the process chamber.

### Technical Solution

A substrate processing apparatus according to an embodiment of the present inventive concept may include: a process chamber having an opening at one side thereof; a process gas supply unit configured to supply a process gas comprising a toxic gas within the process chamber; an exhaust unit configured to exhaust an inside of the process chamber; an opening/closing means configured to open and close the opening of the process chamber; and a control unit configured to detect the supply of the toxic gas so as to interlock the opening/closing means and release the interlock of the opening/closing means according to an internal pressure of the process chamber.

The process gas supply part may include a first supply line through which the toxic gas is supplied and in which at least one of a valve or a flow controller is installed, and the control unit may be configured to detect at least one of an open of the valve or a gas flow of the flow controller so as to interlock the opening/closing means in the state in which the opening is closed.

The substrate processing apparatus may further include: a purge gas supply unit configured to supply a purge gas within the process chamber; and a pressure measuring unit configured to measure the internal pressure of the process chamber, wherein the control unit may be configured to release the interlock of the opening/closing means when the pressure measured by the pressure measuring unit while supplying the purge gas in a state in which the valve is closed, or the gas flow of the flow controller is not detected is maintained to a pressure that is equal to or less than a reference pressure for a pressure maintenance time.

The reference pressure may be experimentally determined through a preliminary test performed under the same conditions as the processing process using the toxic gas.

The control unit may be configured to set the pressure maintenance time to be a time that is equal to or longer than a residence time of the toxic gas using the residence time of the toxic gas in the process chamber, which is measured in the preliminary test.

The control unit may be configured to set the reference pressure as the internal pressure of the process chamber, which is measured while supplying the purge gas at a flow rate that is the same as a flow rate supplied into the process chamber in a purge process of supplying the purge gas.

The pressure maintenance time may be determined according to a length of the first supply line and a volume velocity of the toxic gas.

The substrate processing apparatus may further include: a substrate boat in which a plurality of substrates are loaded in multiple stages and which is accommodated in the process chamber; and a loading chamber provided at one side of the process chamber to provide a space in which the plurality of substrates are loaded on the substrate boat, wherein the opening/closing means may include: a shutter part provided at one side of the process chamber to open and close the opening; and a cover part coupled to a lower end of the substrate boat to open and close the opening according to ascent and descent of the substrate boat, wherein the cover part may be configured to close the opening while the substrate boat is accommodated in the process chamber.

A method for operating a substrate processing apparatus according to another embodiment of the present inventive concept may include: closing an opening defined at one side of a process chamber to perform a processing process using a toxic gas; detecting supply of the toxic gas; interlocking an opening/closing means for opening and closing the opening; and releasing the interlock of the opening/closing means according to an internal pressure of the process chamber.

The detecting the supply of the toxic gas may include at least one of: detecting an open of a valve installed in a first supply line that supplies the toxic gas; or detecting a gas flow through a flow controller installed in the first supply line, wherein, in the interlocking the opening/closing means, when at least one of the open of the valve or the gas flow of the flow controller is detected, the opening/closing means may be interlocked in a state in which the opening is closed.

The method may further include: supplying a purge gas into the process chamber; and measuring an internal pressure of the process chamber, wherein, in the releasing the interlock of the opening/closing means, when a pressure measured in the measuring the internal pressure of the process chamber while supplying the purge gas in a state, in which the valve is closed, or a gas flow of the flow controller is not detected, is maintained to a pressure that is equal to or less than a reference pressure for a pressure maintenance time, the interlock of the opening/closing means may be released.

The method may further include setting the reference pressure, wherein the setting the reference pressure may include determining the reference pressure according to results of a preliminary test performed under the same conditions as the processing process.

The method may further include setting a pressure maintenance time, wherein the setting the pressure maintenance time may include receiving a residence time of the toxic gas within the process chamber, which is measured in the preliminary test.

The method may further include setting the reference pressure, wherein the setting the reference pressure may include receiving the internal pressure of the process chamber, which is measured while supplying the purge gas at the same flow rate as the flow rate supplied into the process chamber in the supplying the purge gas.

The method may further include setting the pressure maintenance time, wherein the setting the pressure maintenance time may include receiving a residence time of the toxic gas, which is calculated using a length of the first supply line and a volume velocity of the toxic gas.

### Advantageous Effects

In the substrate processing apparatus according to the embodiment of the present inventive concept, the supply of the toxic gas may be detected through the control unit to interlock the opening/closing means, and then, the interlock of the opening/closing means may be released according to the internal pressure of the process chamber to block the opening of the process chamber until the toxic gas within the process chamber is completely exhausted, thereby preventing the toxic gas remaining in the process chamber from leaking to the outside due to the open of the opening before the toxic gas is completely exhausted. Thus, the safety accident caused by the toxic gas may be prevented from occurring, and the situation in which all the devices within the semiconductor manufacturing facility (FAB) are shut down due to the leaking of the toxic gas may be prevented.

Here, the internal pressure of the process chamber may be measured, and when the measured pressure is maintained to be equal to or less than the reference pressure for the pressure maintenance time, the interlock of the opening/closing means may be released to prevent the situation (or accident) in which the toxic gas remains in the process chamber from occurring by opening the opening of the process chamber without additionally mounting the separate device for detecting the toxic gas remaining in the process chamber. Here, when the internal pressure of the process chamber is equal to or less than the reference pressure, the interlock of the opening/closing means may be maintained for the pressure maintenance time equal to or longer than the residence time of the toxic gas, rather than the immediate open of the opening of the process chamber, to more effectively prevent the opening from being opened before the toxic gas is completely exhausted.

### BRIEF DESCRIPTION OF THE DRAWINGS

FIG. 1 is a schematic cross-sectional view illustrating a substrate processing apparatus according to an embodiment of the present inventive concept.

FIG. 2 is a conceptual view illustrating a connection relationship between components of the substrate processing apparatus according to an embodiment of the present inventive concept.

FIG. 3 is a view illustrating an opening/closing means according to an embodiment of the present inventive concept.

FIG. 4 is a flowchart illustrating an operating method of a substrate processing apparatus according to another embodiment of the present inventive concept.

### MODE FOR CARRYING OUT THE INVENTIVE CONCEPT

Hereinafter, specific embodiments will be described in more detail with reference to the accompanying drawings. The present inventive concept may, however, be embodied in different forms and should not be construed as limited to the embodiments set forth herein. Rather, these embodiments are provided so that this inventive concept will be thorough and complete, and will fully convey the scope of the present disclosure to those skilled in the art. In the descriptions, the same elements are denoted with the same reference numerals. In the figures, the dimensions of layers and regions are exaggerated for clarity of illustration. Like reference numerals refer to like elements throughout.

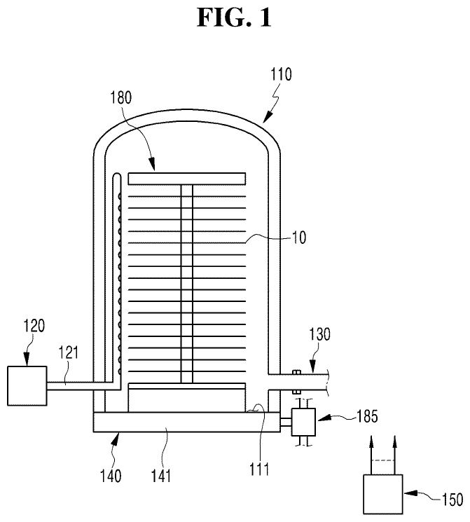

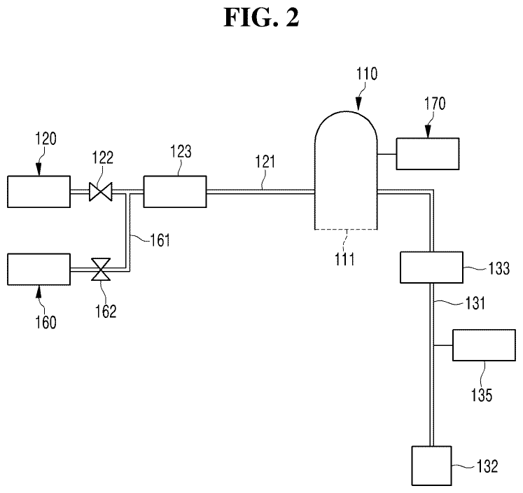

FIG. 1 is a schematic cross-sectional view illustrating a substrate processing apparatus according to an embodiment of the present inventive concept, and FIG. 2 is a conceptual view illustrating a connection relationship between components of the substrate processing apparatus according to an embodiment of the present inventive concept.

Referring to FIGS. 1 and 2, a substrate processing apparatus 100 according to an embodiment of the present inventive concept may include a process chamber 110 having an opening 111 at one side thereof; a process gas supply unit 120 that supplies a process gas containing a toxic gas into the process chamber 110; an exhaust unit 130 that exhausts an inside of the process chamber 110; an opening/closing means 140 that opens and closes the opening 111 of the process chamber 110; and a control unit 150 that detects the supply of the toxic gas to interlock the opening/closing means 140 and release the interlock of the opening/closing means 140 according to an internal pressure of the process chamber 110.

The process chamber 110 may provide a processing space for a substrate 10 such as a wafer, and may have the opening 111 at one side (e.g., a lower end), and the substrate 10 may be loaded into the processing space (i.e., into the process chamber) through the opening 111 so that a processing process is performed on a single substrate or a plurality of substrates 10. For example, the process chamber 110 may be a process tube made of a heat-resistant material such as quartz or ceramic in a cylindrical shape with an upper portion closed and a lower portion opened, and the plurality of substrates 10 may be accommodated inside the process chamber 110 so that a process of processing the substrate 10 is performed in a batch-type. Here, the processing space may be a space that accommodates a substrate boat 180 on which the plurality of substrates 10 are laminated in a longitudinal direction of the process chamber 110, and in which the processing process (e.g., a deposition process) for the substrates 10 is performed.

The process gas supply unit 120 may supply the process gas containing the toxic gas into the process chamber 110, supply a deposition gas for a deposition process into the process chamber 110, and also supply a cleaning gas for cleaning the inside of the process chamber 110. Here, the process gas may include the deposition gas or the cleaning gas. The deposition gas may contain the toxic gas, the cleaning gas may contain the toxic gas, or both the deposition gas and the cleaning gas may contain the toxic gas. For example, the toxic gas may be ammonia (NH₃), hydrogen fluoride (HF), fluorine (F₂), chlorine (Cl₂), hydrogen chloride (HCL), dichloro silane (DCS, SiH₂Cl₂), dichloroethane (DCE, C₂H₄Cl₂), nitric oxide (NO), nitrogen oxide (NOₓ), nitrous oxide (N₂O), etc.

The exhaust unit 130 may exhaust the inside of the process chamber 110 and may communicate with the inside (i.e., the processing space) of the process chamber 110 to exhaust process residue within the processing space to the outside. For example, the exhaust unit 130 may include an exhaust line 131 connected to the process chamber 110. The exhaust line 131 may have one side (or one end) connected to the process chamber 110 to communicate with the exhaust port 112 of the process chamber 110, and the other side (or the other end) connected to a vacuum pump 132. Thus, the process residue may be discharged from the processing space and then exhausted to the outside. Here, an exhaust valve 133 may be installed in the exhaust line 131, and the exhaust valve 133 may be provided as an adaptive pressure control (APC) valve to generate vacuum in the process chamber 110 and adjust a vacuum pressure. The exhaust unit 130 may further include a toxic gas dilution part (not shown) connected to the exhaust line 131 to dilute the toxic gas discharged through the exhaust line 131. The toxic gas dilution part (not shown) may be connected to the exhaust line 131 to dilute the toxic gas discharged through the exhaust line 131 and also may dilute the toxic gas to be discharged to the outside. For example, after collecting the process residue containing the toxic gas in a certain space, the collected process residue may be diluted with nitrogen (N₂) or the like and then discharged to the outside in a non-toxic state.

The opening/closing means 140 may open and close the opening 111 of the process chamber 110 and may block (or prevent) the toxic gas from leaking (or being discharged) out of the process chamber 110 by blocking (or closing) the opening 111 during the processing process using the toxic gas.

The control unit 150 may detect the supply of the toxic gas to interlock the opening/closing means 140 during the processing process using the toxic gas, and after the processing process using the toxic gas (or the supply of the toxic gas) is terminated (or completed), the interlock of the opening/closing means 140 may be released according to the internal pressure of the process chamber 110. For example, for the processing process using the toxic gas, the opening/closing means 140 may be interlocked before or after the supply of the toxic gas starts, and the interlock of the opening/closing means 140 may be released when the internal pressure of the process chamber 110 is equal to or less than a reference pressure after the supply of the toxic gas is ended (or stopped).

Thus, the opening 111 may be prevented from being opened before the toxic gas is completely (or entirely) escaped (or exhausted) within the process chamber 110, and thus, the toxic gas remaining within the process chamber 110 may be fundamentally blocked (or prevented) from leaking to the outside.

Thus, the substrate processing apparatus 100 according to the present inventive concept may detect the supply of the toxic gas through the control unit 150 to interlock the opening/closing means 140 and then release the interlock of the opening/closing means 140 according to the internal pressure of the process chamber 110, thereby blocking the opening 111 of the process chamber 110 from being opened until the toxic gas is completely exhausted from the inside of the process chamber 110 and preventing the toxic gas remaining within the process chamber 110 from leaking to the outside due to the open of the opening 111 before the toxic gas is completely exhausted. Thus, the safety accident caused by the toxic gas may be prevented from occurring, and the situation in which all the devices within the semiconductor manufacturing facility (FAB) are shut down due to the leaking of the toxic gas may be prevented.

The process gas supply unit 120 may supply the toxic gas and may include a first supply line 121 in which at least one of a (first) valve 122 or a (first) flow controller 123 is installed. The first supply line 121 may supply the toxic gas to the process chamber 110 by connecting a (first) gas supply source (or gas storage source) that supplies the toxic gas to the process chamber 110, and at least one of a valve 122 or a flow controller 123 may be installed. Here, the valve 122 may turn on/off the supply (or flow) of the toxic gas, and the flow controller 123 may control the flow (or flow rate) of the toxic gas or sense the flow (or flow rate) of the toxic gas. Here, the control unit 150 may detect at least one of the open of the valve 122 or the gas flow of the flow controller 123 to interlock the opening/closing means 140 in the state in which the opening 111 is closed. When the valve 122 is opened, or the flow of the gas is detected by the flow controller 123, the control unit 150 may determine that the toxic gas is supplied to interlock the opening/closing means 140 in the state in which the opening/closing means 140 closes the opening 111.

For example, the control unit 150 may include a valve sensor (not shown) that detects the opening and closing of the valve 122 and may detect the open (state) of the valve 122 through the valve sensor (not shown). In addition, when the gas flow is detected in the flow controller 123, the control unit 150 may detect the gas flow in the flow controller 123 by receiving (or transmitting) a flow detection signal from the flow controller 123. The supply of the toxic gas may be determined by detecting only one of the open of the valve 122 and the gas flow of the flow controller 123, but in order to improve accuracy of the determination, when all of the open of the valve 122 and the gas flow of the flow controller 123 are detected, it may be preferable to determine that the toxic gas is supplied.

The substrate processing apparatus 100 according to the present inventive concept may further include: a purge gas supply unit 160 that supplies a purge gas into the process chamber 110; and a pressure measuring unit 170 that measures the internal pressure of the process chamber 110.

The purge gas supply unit 160 may supply the purge gas into the process chamber 110 to purge the toxic gas remaining in the process chamber 110. Here, the purge gas may include a nitrogen (N₂) gas or an inert gas such as argon (Ar), helium (He), or neon (Ne). For example, the purge gas supply unit 160 may supply the purge gas into the process chamber 110 after the processing process using the toxic gas is terminated to stop (interrupt) the supply of the toxic gas, thereby performing a purge process, and (even) after the processing process using the toxic gas is completed, the process residue such as the toxic gas remaining in the process chamber 110 may be purged, and the purged process residue may be exhausted through the exhaust unit 130. In addition, the purge gas supply unit 160 may supply the purge gas through a purge line 161, and the supply of the purge gas may be turned on/off by the purge valve 162 installed in the purge line 161. The purge line 161 of the purge gas supply unit 160 may be connected to (or communicate with) the first supply line 121. In this case, the toxic gas remaining in the first supply line 121 may be purged.

The pressure measuring unit 170 may measure the internal pressure of the process chamber 110, directly measure the internal pressure of the process chamber 110, or measure the internal pressure of the chamber 110 computationally (or indirectly) through other measurement value(s) measured directly or indirectly. For example, the pressure measuring unit 170 may be connected to the process chamber 110 as illustrated in FIG. 2 to (directly) measure the internal pressure of the process chamber 110, but may also measure a vacuum level and/or the vacuum pressure (or exhaust pressure) of the process chamber 110 through a vacuum sensor (not shown) connected to the exhaust line 131 to (indirectly) measure the internal pressure of the process chamber 110 with the measured vacuum level and/or the vacuum pressure of the process chamber 110, but is not limited thereto, and it is sufficient to measure the internal pressure of the process chamber 110.

When the pressure measured by the pressure measuring unit 170 is maintained to be equal to or less than the reference pressure for a pressure maintenance time while supplying the purge gas in the state in which the valve 122 is closed, or the gas flow of the flow controller 123 is not detected, the release control unit 150 may the interlock of the opening/closing means 140. The control unit 150 may determine that the supply of the toxic gas is stopped (or interrupted) when the valve 122 is closed, or the gas flow is not detected in the flow controller 123, and also, the control unit 150 may determine that the supply of the toxic gas is supported through either the detection of the closing of the valve 122 or the non-detection of the gas flow by the flow controller 123, but when the valve 122 is closed, and the gas flow is not detected by the flow controller 123, it may be preferable to determine that the supply of the toxic gas is stopped.

When the control unit 150 may determine that the supply of the toxic gas is stopped, the purge gas supply unit 160 may supply the purge gas to purge the toxic gas remaining in the process chamber 110 and/or the first supply line 121, and the control unit 150 may maintain the supply of the toxic gas in the stopped state in the state in which the purge gas supply unit 160 supplies the purge gas after the supply of the toxic gas is stopped.

The purge process may be performed while supplying the purge gas from the purge gas supply unit 160 while the valve 122 is closed, or the gas flow of the flow controller 123 is not detected to be maintained in the state in which the supply of the toxic gas is stopped, and the pressure measuring unit 170 may measure the internal pressure of the process chamber 110 while performing the purge process.

Here, when the internal pressure of the process chamber 110 measured by the pressure measuring unit 170 is equal to or less than the reference pressure, it may be determined that there is no toxic gas remaining in the process chamber 110. However, since the toxic gas remaining in the first supply line 121 is purged and then supplied into the process chamber 110, and the toxic gas remaining in the exhaust line 131 flows backward to leak to the outside due to the open of the opening 111, the interlock of the opening/closing means 140 may be released immediately, but may be released (only) when the pressure is maintained to be equal to or less than the reference pressure for the pressure maintenance time. Thus, the interlock 41 the opening/closing means 140 may be maintained without releasing the interlock of the opening/closing means 140 until the toxic gas is completely escaped from the process chamber 110, and even after the interlock of the opening/closing means 140 is released, the toxic gas remaining in the process chamber 110 may be prevented from remaining to fundamentally block the toxic gas remaining in the process chamber 110 from leaking to the outside.

When the toxic gas leaks to the outside and then is escaped into an external environment, a safety accident caused by the toxic gas may occur and be harmful to the human body, and also, there may also be a problem in that all tens or hundreds of devices within the semiconductor manufacturing facility have to stop operations. Therefore, it is very important to release the interlock the opening/closing means 140 through the control unit 150 only when the toxic gas is completely released from the inside of the process chamber 110.

Here, the reference pressure may be experimentally determined through a preliminary test performed under the same conditions as the processing process using the toxic gas. For example, in the preliminary test performed under the same conditions as the processing process using the toxic gas, the internal pressure of the process chamber 110 may be measured when the toxic gas is completely released from the process chamber 110, and thus, there is no toxic gas remaining in the process chamber 110, and the measured pressure (or the internal pressure of the process chamber) may be used as the reference pressure. The substrate processing apparatus 100 of the present inventive concept may further include a reference pressure storage unit (not shown) in which the reference pressure is stored for each processing process, such as the deposition process and the cleaning process, and also, the reference pressure(s) obtained by performing the preliminary test for each processing process may be stored in the reference pressure storage unit (not shown), and the control unit 150 may read the reference pressure from the reference pressure storage unit (not shown) for each processing process to determine the releasing (timing) of the interlock of the opening/closing means 140.

Here, the control unit 150 may set the pressure maintenance time to be equal to or longer than a residence time of the toxic gas by using the residence time of the toxic gas in the process chamber 110 measured in the preliminary test. That is, the pressure maintenance time may be set to be equal to or longer than the residence time of the toxic gas by measuring the residence time of the toxic gas in the process chamber 110 in the preliminary test. In the preliminary test, the residence time of the toxic gas within the process chamber 110 may be measured, and also, the residence time may be measured for each type of toxic gas, and the measured residence time may be stored for each type of toxic gas in a residence time storage unit (not shown), etc. Here, the substrate processing apparatus 100 of the present inventive concept may further include the residence time storage unit (not shown) in which the residence time is stored according to the type of toxic gas, and thus, the residence time may be measured and stored in the residence time storage unit (not shown) while supplying the purge gas to purge the inside of the process chamber 110 until the toxic gas is not contained in the process residue discharged through the exhaust line 131, and the residence time may be measured according to the type of toxic gas and stored in the residence time storage unit (not shown).

For example, a gas detector 135 such as a self-plasma optical emission spectroscopy (SP-OES) may be installed in an exhaust port 112 and/or an exhaust line 131 of the process chamber 110 to detect whether the process residue (or exhaust gas) discharged through the exhaust port 112 to the exhaust line 131 contains the toxic gas, and a time until the process residue discharged through the exhaust line 131 does not contain the toxic gas may be set as the residence time of the toxic gas. Here, a start time of the residence time may be a time elapsed after the supply of the toxic gas is stopped, may be a time during the performing of the purge process, or may be a time when the purge process (or the supply of the purge gas) starts.

The pressure maintenance time may be set to be equal to or longer than the residence time of the toxic gas to maintain the internal pressure of the process chamber 110 to be equal to or less than the reference pressure for a time that is equal to or longer than the residence time of the toxic gas, and thus, the toxic gas may be entirely (or completely) removed (or exhausted) within the process chamber 110 without the toxic gas remaining in the process chamber 110, and in the state in which there is no toxic gas remaining inside the process chamber 110, the interlock of the opening/closing means 140 may be released to open the opening 111 of the process chamber 110. Thus, the toxic gas may be fundamentally blocked (or prevented) from leaking (or being discharged) from the inside of the process chamber 110. Here, in order to fundamentally block the toxic gas from flowing backward into the exhaust line 131 due to the open of the opening 111, it may be desirable to set the pressure maintenance time longer than the residence time of the toxic gas so that the toxic gas is escaped (or purged) from the exhaust line 131.

Here, the control unit 150 may read the residence time from the residence time storage unit (not shown) for each type of toxic gas to set the pressure maintenance time to be equal to or longer than the residence time of the toxic gas based on the residence time.

The pressure maintenance time may be determined through time-based data obtained by detecting the toxic gas through the gas detector 135 installed in the exhaust line 131 from a time point at which the pressure measured by the pressure measuring unit 170 while supplying the purge gas (i.e., the internal pressure of the process chamber) is equal to or less than the reference pressure, and also, the control unit 150 may determine the pressure maintenance time by confirming the time from which the toxic gas is detected to when it is no longer detected based on the time-based data obtained by detecting the toxic gas and may determine that the toxic gas is completely released (or discharged) when the toxic gas is no longer detected. Here, the time-based data obtained by detecting the toxic gas may also be obtained through the preliminary test, and the time-based data may also be obtained by the type of toxic gas.

For example, the control unit 150 may set the reference pressure as the internal pressure of the process chamber 110, which is measured while supplying the purge gas at a flow rate that is the same as the flow rate supplied into the process chamber 110 in the purge process of supplying the purge gas. That is, the reference pressure may be an internal pressure of the process chamber 110, which is measured while supplying the purge gas at the same flow rate as the flow rate supplied into the process chamber 110 in the purge process of supplying the purge gas, and may be an internal pressure of the process chamber 110, which is measured by supplying only the purge gas at the same flow rate as the flow rate supplied into the process chamber 110 in the purge process without any other gas in advance as a separate process, not the (actual) purge process that is performed after the processing process. For each processing process, the flow rate supplied into the process chamber 110 in the purge process may be determined according to the type of toxic gas, and the internal pressure of the process chamber 110 when only the purge gas at the same flow rate as the flow rate supplied into the process chamber 110 in the purge process of each processing process is supplied may be measured. Here, the internal pressure of the process chamber 110 may be measured while supplying the purge gas at a flow rate that is the same as the flow rate supplied into the process chamber 110 in the purge process for each processing process. The internal pressure of the process chamber 110 measured for each processing process may be different, and thus, the reference pressure may be different for each processing process. Here, the measured internal pressure of the process chamber 110 may be stored as the reference pressure in the reference pressure storage unit (not shown) for each processing process.

Since the internal pressure of the process chamber 110, which is measured while supplying the purge gas at the same flow rate as the flow rate supplied into the process chamber 110 in the purge process is a pressure when only the purge gas exists (or flows) inside the process chamber 110 without the toxic gas, when the pressure measured through the pressure measuring unit 170 in the purge process is the same as the internal pressure of the process chamber 110, which is measured while supplying the purge gas at the same flow rate, it may be determined that only the purge gas exists (or flows) inside the process chamber 110 without any other gas such as the toxic gas. Thus, the internal pressure of the process chamber 110, which is measured while supplying the purge gas of the same flow rate, may be used as the reference pressure, and when the pressure measured by the pressure measuring unit 170 is equal to or less than the reference pressure, it may be determined that there is no toxic gas (or the toxic gas does not remain) within the process chamber 110.

When the toxic gas remains in the process chamber 110, the toxic gas may exist in addition to the purge gas, and thus, the pressure measured by the pressure measuring unit 170 becomes higher than the reference pressure. Thus, when the pressure measured by the pressure measuring unit 170 is higher than the reference pressure, it may be determined that the toxic gas (still) remains (or exists) in the process chamber 110.

In addition, the pressure maintenance time may be determined according to a length of the first supply line 121 and a volume velocity of the toxic gas, and the residence time of the toxic gas may be calculated according to a distance from the gas supply source to the exhaust port 112 of the process chamber 110 (e.g., a length of the first supply line+a width of the process chamber) and the volume velocity of the toxic gas, and the pressure maintenance time may be determined to be equal to or longer than the residence time according to the calculated residence time of the toxic gas.

For example, the residence time of the toxic gas may be proportional to the length of the first supply line 121 and inversely proportional to the volume velocity of the toxic gas, and the pressure maintenance time may also be proportional to the length of the first supply line 121 and inversely proportional to the volume velocity of the toxic gas.

In addition, the residence time of the above toxic gas may be expressed by Equation 1.

$${t}_{res .} = \frac{D}{{V}_{vol .}} = \frac{( l + w )}{{V}_{vol .}} \qquad [ Equation 1 ]$$

(Here, tᵣₑₛ. is the residence time of the toxic gas, D is the distance from the gas supply source to the exhaust port of the process chamber, Vᵥₒₗ. is the volume velocity of the toxic gas, l is the length of the first supply line, and w is the width of the process chamber.)

In addition, the volume velocity of the toxic gas may be determined according to a molecular weight of the toxic gas and may increase as the molecular weight of the toxic gas decreases.

The pressure maintenance time may be easily determined by Equation 1, and the pressure maintenance time may be quickly determined by calculating the residence time of the toxic gas without performing a separate process of supplying a gas such as the purge gas into the process chamber 110 in advance.

Thus, the substrate processing apparatus 100 according to the present inventive concept may measure the internal pressure of the process chamber 110 and release the interlock of the opening/closing means 140 when the measured pressure is maintained to be equal to or less than the reference pressure for the pressure maintenance time to prevent the situation (or accident) in which the toxic gas remains in the process chamber 110 from occurring by opening the opening 111 of the process chamber 110 without additionally mounting the separate device for detecting the toxic gas remaining in the process chamber 110. In addition, when the internal pressure of the process chamber 110 is equal to or less than the reference pressure, the interlock of the opening/closing means 140 may be maintained for the pressure maintenance time equal to or longer than the residence time of the toxic gas, rather than the immediate open of the opening 111 of the process chamber 110, to more effectively prevent the opening 111 from being opened before the toxic gas is completely exhausted.

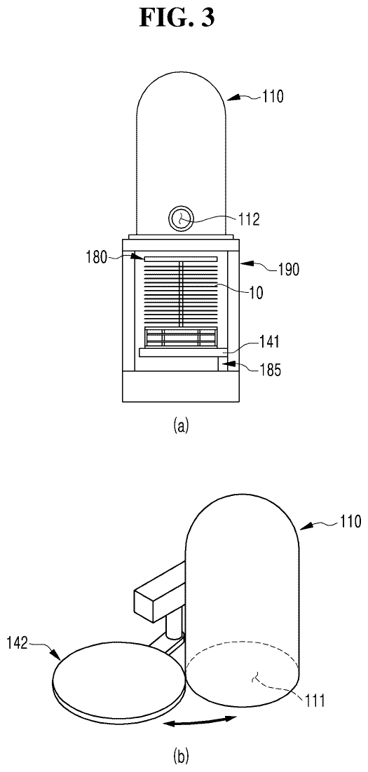

FIG. 3 is a view illustrating the opening/closing means according to an embodiment of the present inventive concept. Here, (a) of FIG. 3 illustrates a cover part, and (b) of FIG. 3 illustrates a shutter part.

Referring to FIG. 3, the substrate processing apparatus 100 according to the present inventive concept may further include: a substrate boat 180 in which the plurality of substrates 10 are loaded in multiple stages and accommodated in the process chamber 110; and a loading chamber 190 provided at one side of the process chamber 110 to provide a space for loading the plurality of substrates 10 onto the substrate boat 180.

The plurality of substrates 10 may be loaded on the substrate boat 180 in the multiple stages, and the substrate boat 180 may be accommodated in the process chamber 110 to perform the process of processing the substrates 10. That is, the plurality of substrates 10 may be loaded on the substrate boat 180 in the multiple stages (or in the vertical direction) to perform the process of processing the substrates 10, and the substrate boat 180 may be provided in the inside (i.e., the processing space) of the process chamber 110 and be accommodated in the internal space (i.e., the processing space) of the process chamber 110 during the process of processing the substrates 10. Here, the substrate boat 180 may be provided in plurality, which are provided respectively inside a plurality of process chambers 110. Here, the substrate boat 180 may be configured to have a plurality of independent spaces in which the plurality of substrates 10 are individually processed.

The loading chamber 190 may be disposed (or provided) at one side (e.g., a lower side) of the process chamber 110 (in the longitudinal direction) and may provide a space for loading the plurality of substrates 10 onto the substrate boat 180, and the plurality of substrates 10 may be loaded into the loading chamber 190 and loaded onto the substrate boat 180 in the multiple stages. In addition, in the loading chamber 190, the substrate boat 180 loaded with the plurality of substrates 10 may be elevated by a boat elevator 185 and accommodated in the internal space of the process chamber 110 to perform the process of processing the substrates 10. For example, the loading chamber 190 may have an opened upper portion so that the substrate boat 180 is elevated, and a passage through which the substrates 10 enter and exit may be defined at one side of the loading chamber 190 (in the width direction) so that the plurality of substrates 10 are loaded. Here, the loading chamber 190 may be connected to a transfer chamber (not shown) and have a passage connected to the transfer chamber (not shown), and thus, the substrate 10 may be loaded into the loading chamber 190 from the transfer chamber (not shown) through the passage. A gate valve (not shown) may be installed outside the passage, and the passage may be opened and closed by the gate valve (not shown).

The opening/closing means 140 may include a cover part 141 that is coupled to a lower end of the substrate boat 180 to open and close the opening part 111 according to ascent and descent of the substrate boat 180; and a shutter part 142 that is provided at one side of the process chamber 110 to open and close the opening part 111. The cover part 141 may be connected to the lower end of the substrate boat 180 and may be elevated together with the substrate boat 180 according to the elevation of the substrate boat 180 by the boat elevator 185 to open and close the opening 111. Here, the cover part 141 may close the opening 111 while the substrate boat 180 is accommodated in the process chamber 110, and the processing process for the substrate 10 may be performed in the state in which the opening 111 is closed by the cover part 141, and after the processing process is completed (or ended), the cover part 141 may descend together with the substrate boat 180 to the opening 111.

The shutter part 142 may be provided at one side (e.g., a lower side) of the process chamber 110 to open and close the opening 111. Thus, the shutter part 142 may close the opening 111 when the substrate boat 180 has descended and is positioned in the loading chamber 190, and may open the opening 111 when the substrate boat 180 is accommodated in the process chamber 110 or when the substrate boat 180 is ascending or descending between the process chamber 110 and the loading chamber 190.

For example, the shutter part 142 may open and close the opening 111 by rotating (or revolving) a blocking plate that is capable of blocking the opening 111 around a rotation axis spaced from a center of the blocking plate, as illustrated in (b) of FIG. 3.

The control unit 150 may interlock the cover part 141 in the deposition process that is performed in the state in which the substrate boat 180 is accommodated in the process chamber 110 to close the opening 111 by the cover part 141 and may interlock the shutter part 142 that closes (or shields) the opening 111 in the cleaning process of cleaning the inside of the process chamber 110 in the state in which the substrate boat 180 is not accommodated in the process chamber 110.

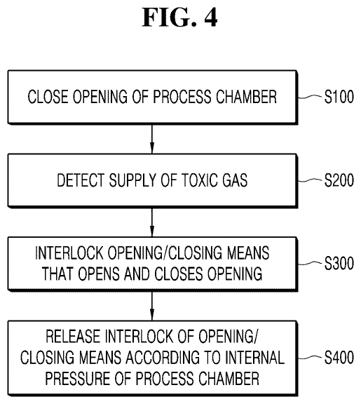

FIG. 4 is a flowchart illustrating an operating method of a substrate processing apparatus according to another embodiment of the present inventive concept.

Referring to FIG. 4, an operating method of a substrate processing apparatus according to another embodiment of the present inventive concept will be described in more detail. However, any duplicated details with those described above in relation to the substrate processing apparatus according to an embodiment of the present inventive concept will be omitted. The method for operating substrate processing apparatus according to another embodiment of the present inventive concept may include a process (S100) of closing an opening defined at one side of a process chamber to perform a processing process using a toxic gas; a process (S200) of detecting supply of the toxic gas; a process (S300) of interlocking an opening/closing means for opening and closing the opening; and a process (S400) of releasing the interlock of the opening/closing means according to an internal pressure of the process chamber.

First, to perform the processing process using toxic gas, the opening defined at one side of the process chamber is closed (S100). In order to perform a processing process using a toxic gas, the opening of the process chamber having the opening at one side may be closed by the opening/closing means, and the processing process using the toxic gas may be performed in the state in which the opening of the process chamber is closed.

Next, the supply of the above toxic gas is detected (S200). Since the toxic gas is harmful to the human body, when the toxic gas leaks out and is escaped into an external environment, a safety accident caused by the toxic gas may occur. This may allow a control unit to detect the supply of the toxic gas so as to prevent the toxic gas from leaking (or being discharged) to the outside by opening the opening of the process chamber during the supply of the toxic gas. As a result, the supply of the toxic gas may be sensed (or detected), and when the supply of the toxic gas is detected, the opening of the process chamber may be prevented from being opened, thereby preventing the toxic gas from leaking to the outside through the opening.

In addition, the opening/closing means for opening and closing the opening is interlocked (S300). When the supply of the toxic gas is detected, the control unit may interlock the opening/closing means for opening and closing the opening to prevent the opening of the process chamber from being opened, and thus, the opening of the process chamber may not be opened during the supply of the toxic gas, and the toxic gas may be prevented from leaking to the outside through the opening.

Then, the interlock of the opening/closing means is released according to an internal pressure of the process chamber (S400). When the supply of the toxic gas is terminated, the control unit may release the interlock of the opening/closing means according to the internal pressure of the process chamber, and after the toxic gas remaining in the process chamber is completely (or entirely) removed (or exhausted) from the inside of the process chamber, the interlock of the opening/closing means may be released to open the opening of the process chamber.

The process (S200) of detecting the supply of the toxic gas may include any one of a process (S211) of detecting opening of a valve installed in a first supply line that supplies the toxic gas; and a process (S212) of detecting a gas flow through a flow controller installed in the first supply line.

The open of the valve installed in the first supply line supplying the toxic gas may be detected (S211). The control unit may detect the open of the valve installed in the first supply line that supplies the toxic gas to detect whether the toxic gas is being supplied, and when the valve is opened, the control unit may determine that the toxic gas is being supplied. For example, the control unit may detect the opening (opened state) of the valve through a valve sensor that detects the opening and closing of the valve.

In addition, the gas flow may be detected through the flow controller installed in the first supply line (S212). The control unit may detect the gas flow through the flow controller installed in the first supply line to detect whether the toxic gas is being supplied, and when the gas flow is detected by the flow controller, it may be determined that the toxic gas is being supplied. For example, the control unit may receive or transmit a flow detection signal from the flow controller to detect the gas flow in the flow controller when the gas flow is detected in the flow controller.

In addition, in the process (S300) of interlocking the opening/closing means, when at least one of the open of the valve or the gas flow of the flow controller is detected, the opening/closing means may be interlocked in the state in which the opening part is closed. When at least one of the open of the valve or the gas flow of the flow controller is detected (or when the valve is opened, or the gas flow is detected by the flow controller), the control unit may determine that the toxic gas is supplied to interlock the opening/closing means in the state in which the opening/closing means closes the opening.

The method for operating the substrate processing apparatus according to the present inventive concept may further include: a process (S350) of supplying a purge gas into the process chamber; and a process (S360) of measuring the internal pressure of the process chamber.

The purge gas may be supplied into the process chamber (S350). The purge gas may be supplied into the process chamber through a purge gas supply unit, and the toxic gas remaining in the process chamber may be purged. For example, the purge gas supply unit may supply the purge gas into the process chamber after the processing process using the toxic gas is terminated to stop (interrupt) the supply of the toxic gas, thereby performing a purge process, and (even) after the processing process using the toxic gas is completed, the process residue such as the toxic gas remaining in the process chamber may be purged, and the purged process residue may be exhausted through the exhaust unit.

In addition, the internal pressure of the process chamber may be measured (S360). The internal pressure of the process chamber may be measured through a pressure measuring unit, and the pressure measuring unit may be connected to the process chamber to (directly) measure the internal pressure of the process chamber or measure a vacuum degree and/or a vacuum pressure (or exhaust pressure) of the process chamber through a vacuum sensor connected to an exhaust line of the exhaust unit, thereby indirectly measuring the internal pressure of the process chamber through the measured vacuum degree and/or vacuum pressure of the process chamber.

In the process (S400) of releasing the interlock of the opening/closing means, the interlock of the opening/closing means may be released when the measured pressure is maintained to be equal to or less than a reference pressure for a pressure maintenance time in the process of measuring the internal pressure of the process chamber while the purge gas is supplied in the state in which the valve is closed, or the gas flow of the flow controller is not detected. The control unit may release the interlock of the opening/closing means when the pressure measured by the pressure measuring unit is maintained to be equal to or less than the reference pressure for the pressure maintenance time in the process of measuring the internal pressure of the process chamber while the purge gas is supplied in the state in which the valve is closed, or the gas flow of the flow controller is not detected. Here, the control unit may determine that the supply of the toxic gas is stopped (or interrupted) when the valve is closed, or the gas flow is not detected in the flow controller, and also, the control unit may determine that the supply of the toxic gas is supported through either the detection of the closing of the valve or the non-detection of the gas flow by the flow controller, but when the valve is closed, and the gas flow is not detected by the flow controller, it may be preferable to determine that the supply of the toxic gas is stopped.

When the control unit may determine that the supply of the toxic gas is stopped, the purge gas supply unit may supply the purge gas to purge the toxic gas remaining in the process chamber and/or the first supply line, and the control unit may maintain the supply of the toxic gas in the stopped state in the state in which the purge gas supply unit supplies the purge gas after the supply of the toxic gas is stopped.

The purge process may be performed while supplying the purge gas from the purge gas supply unit while the valve is closed, or the gas flow of the flow controller is not detected to be maintained in the state in which the supply of the toxic gas is stopped, and the pressure measuring unit may measure the internal pressure of the process chamber while performing the purge process.

Here, when the internal pressure of the process chamber, which is measured by the pressure measuring unit, is equal to or less than the reference pressure, it may be determined that there is no toxic gas remaining in the process chamber. However, since the toxic gas remaining in the first supply line is purged and then supplied into the process chamber, and the toxic gas remaining in the exhaust line flows backward to leak to the outside due to the open of the opening, the interlock of the opening/closing means may be released immediately, but may be released (only) when the pressure is maintained to be equal to or less than the reference pressure for the pressure maintenance time. Thus, the interlock of the opening/closing means may be maintained without releasing the interlock of the opening/closing means until the toxic gas is completely escaped from the process chamber, and even after the interlock of the opening/closing means is released, the toxic gas remaining in the process chamber may be prevented from remaining to fundamentally block the toxic gas remaining in the process chamber from leaking to the outside.

The method for operating the substrate processing apparatus according to the present inventive concept may further include a process (S50) of setting the reference pressure.

The reference pressure may be set (S50). When the toxic gas leaks to the outside and then is escaped into an external environment, a safety accident caused by the toxic gas may occur and be harmful to the human body, and also, there may also be a problem in that all tens or hundreds of devices within the semiconductor manufacturing facility (FAB) have to stop operations. Therefore, it is very important to release the interlock the opening/closing means through the control unit only when the toxic gas is completely released from the inside of the process chamber. For this, an appropriate reference pressure may be set for the control unit.

Here, the process (S50) of setting the reference pressure may include a process (S51) of determining the reference pressure based on results of a preliminary test performed under the same conditions as the processing process.

The reference pressure may be determined based on the results of the preliminary test performed under the same conditions as the processing process (S51). For example, in the preliminary test performed under the same conditions as the processing process using the toxic gas, the internal pressure of the process chamber may be measured when the toxic gas is completely released from the process chamber, and thus, there is no toxic gas remaining in the process chamber, and the measured pressure (or the internal pressure of the process chamber) may be used as the reference pressure. The process (S51) of determining the reference pressure based on the results of the preliminary test may include a process of performing the preliminary test for each processing process such as a deposition process and a cleaning process to respectively store the reference pressure(s) obtained in the reference pressure storage unit and a process of reading the reference pressure stored in the reference pressure storage unit for each processing process by the control unit. Each of the reference pressure(s) obtained by performing the preliminary test for each processing process such as the deposition process and the cleaning process may be stored in the reference pressure storage unit, and the control unit may determine the reference pressure(s) stored in the reference pressure storage unit for each processing process to read the reference pressure stored in the reference pressure storage unit. In addition, the control unit may read the reference pressure from the reference pressure storage unit for each processing process to determine the release (time point) of the interlock of the opening/closing means.

The method for operating the substrate processing apparatus according to the present inventive concept may further include a process (S60) of setting the pressure maintenance time.

The pressure maintenance time may be set (S60). The pressure maintenance time appropriate to the control unit may be set. Here, in the process (S60) of setting the pressure maintenance time, the pressure maintenance time may be set to a time equal to or longer than the residence time of the toxic gas by using a residence time of the toxic gas in the process chamber measured in the preliminary test.

For example, the process (S60) of setting the pressure maintenance time may include a process (S61) of receiving the residence time of the toxic gas in the process chamber measured in the preliminary test.

The residence time of the toxic gas within the process chamber measured in the preliminary test may be received (S61). The control unit may measure the residence time of the toxic gas in the process chamber in the preliminary test, read the residence time of the toxic gas stored in the residence time storage unit, and input the residence time of the toxic gas. In the preliminary test, the residence time of the toxic gas within the process chamber may be measured, and also, the residence time may be measured for each type of toxic gas, and the measured residence time may be stored for each type of toxic gas in a residence time storage unit, etc. For example, a gas detector such as a self-plasma optical emission spectroscopy (SP-OES) may be installed in an exhaust port and/or an exhaust line of the process chamber to detect whether the process residue (or exhaust gas) discharged through the exhaust port to the exhaust line contains the toxic gas, and a time until the process residue discharged through the exhaust line does not contain the toxic gas may be set as the residence time of the toxic gas. Here, a start time of the residence time may be a time elapsed after the supply of the toxic gas is stopped, may be a time during the performing of the purge process, or may be a time when the purge process (or the supply of the purge gas) starts.

The pressure maintenance time may be set to be equal to or longer than the residence time of the toxic gas to maintain the internal pressure of the process chamber to be equal to or less than the reference pressure for a time that is equal to or longer than the residence time of the toxic gas, and thus, the toxic gas may be entirely (or completely) removed (or exhausted) within the process chamber without the toxic gas remaining in the process chamber, and in the state in which there is no toxic gas remaining inside the process chamber, the interlock of the opening/closing means may be released to open the opening of the process chamber. Thus, the toxic gas may be fundamentally blocked (or prevented) from leaking (or being discharged) from the inside of the process chamber. Here, in order to fundamentally block the toxic gas from flowing backward into the exhaust line due to the open of the opening, it may be desirable to set the pressure maintenance time longer than the residence time of the toxic gas so that the toxic gas is escaped (or purged) from the exhaust line.

In addition, the process (S50) of setting the reference pressure may include a process (S52) of receiving the internal pressure of the process chamber, which is measured while supplying the purge gas at a flow rate that is the same as the flow rate supplied into the process chamber in the process (S350) of supplying the purge gas.

In the process (S350) of supplying the purge gas, the internal pressure of the process chamber, which is measured while supplying the purge gas at the flow rate that is the same as the flow rate supplied into the process chamber, may be received (S52). In the process (S350) of supplying the purge gas, the control unit may measure the internal pressure of the process chamber while supplying the purge gas at the flow rate that is same as the flow rate supplied into the process chamber, and read the internal pressure of the process chamber stored as the reference pressure in the reference pressure storage unit to receive the internal pressure of the process chamber. In the process (S350) of supplying the purge gas through the pressure measuring unit, the internal pressure of the process chamber may be measured while supplying the purge gas at the flow rate that is the same as the flow rate supplied into the process chamber, and the measured internal pressure of the process chamber may be (set) as the reference pressure. That is, the reference pressure may be the internal pressure of the process chamber 110, which is measured while supplying the purge gas at the same flow rate as the flow rate supplied into the process chamber in the purge process (the process of supplying the purge gas), and may be an internal pressure of the process chamber, which is measured by supplying only the purge gas at the same flow rate as the flow rate supplied into the process chamber in the purge process without any other gas in advance as a separate process, not the (actual) purge process that is performed after the processing process. For each processing process, the flow rate supplied into the process chamber in the purge process may be determined according to the type of toxic gas, and the internal pressure of the process chamber when only the purge gas at the same flow rate as the flow rate supplied into the process chamber in the purge process of each processing process is supplied may be measured. Here, the internal pressure of the process chamber may be measured while supplying the purge gas at a flow rate that is the same as the flow rate supplied into the process chamber in the purge process for each processing process. The internal pressure of the process chamber measured for each processing process may be different, and thus, the reference pressure may be different for each processing process. Here, the measured internal pressure of the process chamber may be stored as the reference pressure in the reference pressure storage unit for each processing process.

In the process (S350) of supplying the purge gas, since the internal pressure of the process chamber 350, which is measured while supplying the purge gas at the same flow rate as the flow rate supplied into the process chamber is a pressure when only the purge gas exists (or flows) inside the process chamber without the toxic gas, when the pressure measured through the pressure measuring unit in the purge process is the same as the internal pressure of the process chamber, which is measured while supplying the purge gas at the same flow rate, it may be determined that only the purge gas exists (or flows) inside the process chamber without any other gas such as the toxic gas. Thus, the internal pressure of the process chamber, which is measured while supplying the purge gas of the same flow rate, may be used as the reference pressure, and when the pressure measured by the pressure measuring unit is equal to or less than the reference pressure, it may be determined that there is no toxic gas (or the toxic gas does not remain) within the process chamber.

In addition, the process (S60) of setting the pressure maintenance time may include a process (S62) of receiving the residence time of the toxic gas calculated using a length of the first supply line and a volume velocity of the toxic gas.

The residence time of the toxic gas calculated using the length of the first supply line and the volume velocity of the toxic gas may be received (S62). The control unit may receive the residence time of the toxic gas calculated using the length of the first supply line and the volume velocity of the toxic gas, read the residence time of the toxic gas stored in the residence time storage unit by calculating the residence time of the toxic gas using the length of the first supply line and the volume velocity of the toxic gas, or (directly) calculate the residence time using the length of the first supply line and the volume velocity of the toxic gas. The control unit may calculate the residence time of the toxic gas using the length of the first supply line and the volume velocity of the toxic gas and may calculate the residence time of the toxic gas based on a distance from the gas supply source to the exhaust port of the process chamber (e.g., a length of the first supply line+a width of the process chamber) and the volume velocity of the toxic gas, and may determine the pressure maintenance time to be equal to or longer than the residence time of the toxic gas based on the residence time of the toxic gas calculated in this manner. That is, the pressure maintenance time may be determined according to a length of the first supply line and a volume velocity of the toxic gas, and the residence time of the toxic gas may be calculated according to a distance from the gas supply source to the exhaust port of the process chamber and the volume velocity of the toxic gas, and the pressure maintenance time may be determined to be equal to or longer than the residence time according to the residence time of the toxic gas calculated in this manner.

For example, the residence time of the toxic gas may be proportional to the length of the first supply line and inversely proportional to the volume velocity of the toxic gas, and the pressure maintenance time may also be proportional to the length of the first supply line and inversely proportional to the volume velocity of the toxic gas. Here, the volume velocity of the toxic gas may be determined according to a molecular weight of the toxic gas and may increase as the molecular weight of the toxic gas decreases.

The residence time of the toxic gas may be calculated using the length of the first supply line and the volume velocity of the toxic gas to easily determine the pressure maintenance time, and the residence time of the toxic gas may be quickly calculated without performing a separate process of supplying a gas such as the purge gas into the process chamber in advance to determine the pressure maintenance time.

Thus, the supply of the toxic gas may be detected to interlock the opening/closing means, and the interlock of the opening/closing means may be released according to the internal pressure of the above process chamber to block an open of the opening of the process chamber until the toxic gas is completely exhausted from the process chamber, thereby preventing the toxic gas remaining in the process chamber from leaking to the outside due to the open of the opening is before the toxic gas is completely exhausted, and also, the internal pressure of the process chamber may be measured, and the interlock of the opening/closing means may be released when the measured pressure is maintained to be equal to or less than the reference pressure for the pressure maintenance time to prevent a situation (or accident) in which the toxic gas remains inside the above process chamber from occurring while opening the opening of the process chamber even without additionally installing a separate device for detecting the toxic gas remaining in the process chamber.

The opening/closing means may be provided with (two opening/closing means), i.e., a cover part (or first opening/closing means) that is connected to a lower part of a substrate boat, in which a plurality of substrates are loaded in multiple stages, to open and close the opening of the process chamber according to an elevation of the substrate boat, and a shutter part (or second opening/closing means) provided at one side (in a longitudinal direction) of the process chamber to open and close the opening of the process chamber. Thus, the cover part may close the opening so that the deposition process is performed while the substrate boat is accommodated in the process chamber, and the shutter part may close the opening to perform the cleaning process of cleaning the inside of the process chamber in a state in which the substrate boat is not accommodated in the process chamber. Here, in the deposition process in which the substrate boat is accommodated in the process chamber, and which is performed in the state in which the opening is closed by the cover part, the control unit may interlock the cover part, and in the cleaning process in which the inside of the process chamber is cleaned in the state in which the substrate boat is not accommodated in the process chamber, the control unit may interlock the shutter part that closes (or shields) the opening. That is, the cover part and the shutter part may be selectively used to close the opening depending on the processing process, and the opening/closing means, which closes the opening, of the cover part and the shutter part may be interlocked during the processing process.

As described above, in the present inventive concept, the supply of the toxic gas may be detected through the controller to interlock the opening/closing means, and then, the interlock of the opening/closing means may be released according to the internal pressure of the process chamber to block the opening of the process chamber until the toxic gas within the process chamber is completely exhausted, thereby preventing the toxic gas remaining in the process chamber from leaking to the outside due to the open of the opening before the toxic gas is completely exhausted. Thus, the safety accident caused by the toxic gas may be prevented from occurring, and the situation in which all the devices within the semiconductor manufacturing facility are shut down due to the leaking of the toxic gas may be prevented. Here, the internal pressure of the process chamber may be measured, and when the measured pressure is maintained to be equal to or less than the reference pressure for the pressure maintenance time, the interlock of the opening/closing means may be released to prevent the situation in which the toxic gas remains in the process chamber from occurring by opening the opening of the process chamber without additionally mounting the separate device for detecting the toxic gas remaining in the process chamber. Here, when the internal pressure of the process chamber is equal to or less than the reference pressure, the interlock of the opening/closing means may be maintained for the pressure maintenance time longer than the residence time of the toxic gas, rather than the immediate open of the opening of the process chamber, to more effectively prevent the opening from being opened before the toxic gas is completely exhausted.

Although preferred embodiments of the present inventive concept have been described with reference to a number of illustrative embodiments thereof, the embodiments of the present inventive concept are not limited to the foregoing embodiments, and thus, it should be understood that numerous other modifications and embodiments may be devised by those skilled in the art that will fall within the spirit and scope of the principles of this inventive concept. Hence, the real protective scope of the present inventive concept shall be determined by the technical scope of the accompanying claims.

1. A substrate processing apparatus comprising:
a process chamber having an opening at one side thereof;
a process gas supply unit configured to supply a process gas comprising a toxic gas within the process chamber;
an exhaust unit configured to exhaust an inside of the process chamber;
an opening/closing means configured to open and close the opening of the process chamber; and
a control unit configured to detect the supply of the toxic gas so as to interlock the opening/closing means and release the interlock of the opening/closing means according to an internal pressure of the process chamber.

2. The substrate processing apparatus of claim 1, wherein the process gas supply part comprises a first supply line through which the toxic gas is supplied and in which at least one of a valve or a flow controller is installed, and
the control unit is configured to detect at least one of an open of the valve or a gas flow of the flow controller so as to interlock the opening/closing means in the state in which the opening is closed.

3. The substrate processing apparatus of claim 2, further comprising:
a purge gas supply unit configured to supply a purge gas within the process chamber; and
a pressure measuring unit configured to measure the internal pressure of the process chamber,
wherein the control unit is configured to release the interlock of the opening/closing means when the pressure measured by the pressure measuring unit while supplying the purge gas in a state in which the valve is closed, or the gas flow of the flow controller is not detected is maintained to a pressure that is equal to or less than a reference pressure for a pressure maintenance time.

4. The substrate processing apparatus of claim 3, wherein the reference pressure is experimentally determined through a preliminary test performed under the same conditions as the processing process using the toxic gas.

5. The substrate processing apparatus of claim 4, wherein the control unit is configured to set the pressure maintenance time to be a time that is equal to or longer than a residence time of the toxic gas using the residence time of the toxic gas in the process chamber, which is measured in the preliminary test.

6. The substrate processing apparatus of claim 3, wherein the control unit is configured to set the reference pressure as the internal pressure of the process chamber, which is measured while supplying the purge gas at a flow rate that is the same as a flow rate supplied into the process chamber in a purge process of supplying the purge gas.

7. The substrate processing apparatus of claim 3, wherein the pressure maintenance time is determined according to a length of the first supply line and a volume velocity of the toxic gas.

8. The substrate processing apparatus of claim 1, further comprising:
a substrate boat in which a plurality of substrates are loaded in multiple stages and which is accommodated in the process chamber; and
a loading chamber provided at one side of the process chamber to provide a space in which the plurality of substrates are loaded on the substrate boat,
wherein the opening/closing means comprises:
a shutter part provided at one side of the process chamber to open and close the opening; and
a cover part coupled to a lower end of the substrate boat to open and close the opening according to ascent and descent of the substrate boat,
wherein the cover part is configured to close the opening while the substrate boat is accommodated in the process chamber.

9. A method for operating a substrate processing apparatus, the method comprising:
closing an opening defined at one side of a process chamber to perform a processing process using a toxic gas;
detecting supply of the toxic gas;
interlocking an opening/closing means for opening and closing the opening; and
releasing the interlock of the opening/closing means according to an internal pressure of the process chamber.

10. The method of claim 9, wherein the detecting the supply of the toxic gas comprises at least one of:
detecting an open of a valve installed in a first supply line that supplies the toxic gas; or
detecting a gas flow through a flow controller installed in the first supply line,
wherein, in the interlocking the opening/closing means, when at least one of the open of the valve or the gas flow of the flow controller is detected, the opening/closing means is interlocked in a state in which the opening is closed.

11. The method of claim 10, further comprising:
supplying a purge gas into the process chamber; and
measuring an internal pressure of the process chamber,
wherein, in the releasing the interlock of the opening/closing means, when a pressure measured in the measuring the internal pressure of the process chamber while supplying the purge gas in a state, in which the valve is closed, or a gas flow of the flow controller is not detected, is maintained to a pressure that is equal to or less than a reference pressure for a pressure maintenance time, the interlock of the opening/closing means is released.

12. The method of claim 11, further comprising setting the reference pressure,
wherein the setting the reference pressure comprises determining the reference pressure according to results of a preliminary test performed under the same conditions as the processing process.

13. The method of claim 12, further comprising setting a pressure maintenance time,
wherein the setting the pressure maintenance time comprises receiving a residence time of the toxic gas within the process chamber, which is measured in the preliminary test.

14. The method of claim 11, further comprising setting the reference pressure,
wherein the setting the reference pressure comprises receiving the internal pressure of the process chamber, which is measured while supplying the purge gas at the same flow rate as the flow rate supplied into the process chamber in the supplying the purge gas.

15. The method of claim 11, further comprising setting the pressure maintenance time,
wherein the setting the pressure maintenance time comprises receiving a residence time of the toxic gas, which is calculated using a length of the first supply line and a volume velocity of the toxic gas.
